(19) United States
(12) Patent Application Publication
(10) Pub. No.: US 2023/0004293 A1
(43) Pub. Date: Jan. 5, 2023

(54) CONTROLLER, MEMORY SYSTEM, AND METHOD OF CONTROLLING MEMORY

(71) Applicant: SONY SEMICONDUCTOR SOLUTIONS CORPORATION, KANAGAWA (JP)

(72) Inventors: HIDEAKI OKUBO, KANAGAWA (JP); KENICHI NAKANISHI, KANAGAWA (JP)

(21) Appl. No.: 17/777,868

(22) PCT Filed: Oct. 13, 2020
(86) PCT No.: PCT/JP2020/038682

§ 371 Date: May 18, 2022

(30) Foreign Application Priority Data
Nov. 27, 2019 (JP) 2019-214713

(51) Int. Cl. G06F 3/06

(52) U.S. Cl. CPC G06F 3/064; G06F 3/0656; G06F 3/0679; G06F 3/0604

(57) ABSTRACT

An object is to reduce the number of writes of information managed by a controller to a non-volatile memory. A controller according to one aspect of the present invention includes: a first interface unit connected to a non-volatile memory including a plurality of blocks of memory cells that enter into both a first state and a second state and in which a plurality of addresses is allocated to the plurality of blocks; an information holding unit that holds first information; and a control unit that reads first data from a first block of the non-volatile memory via the first interface unit, specifies the memory cell in the second state among the memory cells in the first block and writes second data for causing the specified memory cell in the second state to transition to the first state, and selects one of the first information and the first data on the basis of the address of the first block and writes the selected first information or first data to the first block.

### TECHNICAL FIELD

The present disclosure relates to a controller of a non-volatile memory, a memory system, and a method of controlling a memory.

### BACKGROUND ART

A system including a memory module and a host is generally known. The memory module includes a non-volatile memory such as a solid state drive (SSD) and a controller. There is a method in which the host determines the life of the memory module by using information indicating a state of the memory module. Examples of the information indicating the state of the memory module include a cumulative capacity of data written to the memory module and a cumulative capacity of data read from the memory module.

In a case where the controller of the memory module receives a request to acquire the cumulative capacity of writes, the cumulative capacity of reads, and the like from the host, the controller needs to supply the cumulative capacities of writes and reads to the host. Therefore, the controller needs to constantly calculate the cumulative capacities of writes and reads and hold the calculated information in preparation for receiving an acquisition request from the host.

When power supply to the controller from the host is momentarily interrupted, the held information is erased. Therefore, the controller needs to write the information to the non-volatile memory in preparation for the momentary interruption of the power supply. However, if the information is written to the non-volatile memory every time when the information is updated, the number of writes increases, and this accelerates deterioration of memory cells.

Japanese Patent No. 6423282 proposes a method of selectively using refresh processing and check processing in accordance with a state of a non-volatile memory, for example, the number of accesses to a plurality of blocks included in the memory. The check processing is processing of determining whether to perform the refresh processing on the basis of a bit error rate of data read from the blocks. Even if this method is used, however, the number of writes of information cannot be effectively reduced.

### CITATION LIST

### Patent Document

Patent Document 1: Japanese Patent No. 6423282

### SUMMARY OF THE INVENTION

### Problems to be Solved by the Invention

The present disclosure provides a controller, a memory system, and a method of controlling a memory capable of reducing the number of writes of information managed by the controller to a non-volatile memory.

### Solutions to Problems

A controller according to one aspect of the present invention includes: a first interface unit connected to a non-volatile memory including a plurality of blocks of memory cells that enter into both a first state and a second state and in which a plurality of addresses is allocated to the plurality of blocks; an information holding unit that holds first information; and a control unit that reads first data from a first block of the non-volatile memory via the first interface unit, specifies the memory cell in the second state among the memory cells in the first block and writes second data for causing the specified memory cell in the second state to transition to the first state, and selects one of the first information and the first data on the basis of the address of the first block and writes the selected first information or first data to the first block.

The control unit writes the first information in a case where the address of the first block is a first address and writes the first data in a case where the address of the first block is not the first address.

The memory cell includes a selector and a variable resistor connected in series,

the first state and the second state are different states of the variable resistor, and

the selector is turned on at a voltage equal to or higher than a threshold, and the threshold increases as time elapses after the selector is turned on.

The first state is a low resistance state, and the second state is a high resistance state.

The control unit determines whether the memory cells of the first block are in the first state or the second state on the basis of the first data.

A buffer that holds the first data read from the first block of the non-volatile memory is provided.

The first data includes an error correction code,

an error correction unit that corrects an error of the first data on the basis of the error correction code is provided, and

the control unit writes the first data subjected to the error correction to the first block.

The first information indicates a state of the non-volatile memory, and

the control unit updates the first information of the information holding unit in accordance with the state of the non-volatile memory.

The first information includes a cumulative value of the number of writes or the number of reads of the non-volatile memory, and

the control unit updates the first information of the information holding unit every time when the non-volatile memory is written or read.

A second interface unit connected to a host system is provided,

the control unit receives a write or read command from the host system via the second interface unit and performs write to or read from the non-volatile memory in response to the command,

the first information includes a cumulative value of the number of executions of the command, and

the control unit updates the first information of the information holding unit every time when the command is executed.

The first information includes a startup time of the non-volatile memory, and

the control unit updates the first information of the information holding unit as time elapses.

The first state corresponds to a first value,

the second state corresponds to a second value, and

the control unit does not write the second data in a case where all bits of the first data have the first value.

The first state corresponds to a first value,

the second state corresponds to a second value, and

the control unit does not write the first data in a case where the address of the first block is not the first address and all bits of the first data have the first value.

The control unit does not write the first data in a case where the address of the first block is not the first address and the address of the first block is a second address.

The second address is an address of an unused block among the plurality of blocks.

The second address is an address of a block storing unnecessary data among the plurality of blocks.

The control unit sequentially selects the plurality of blocks in the non-volatile memory, and defines the selected block as the first block.

A memory system according to one aspect of the present invention includes:

a non-volatile memory that includes a plurality of blocks of memory cells that enter into both a first state and a second state and in which a plurality of addresses is allocated to the plurality of blocks; and

a controller including an information holding unit that holds first information and a control unit, in which:

the control unit

reads first data from a first block of the non-volatile memory,

specifies the memory cell in the second state among the memory cells in the first block and writes second data for causing the specified memory cell in the second state to transition to the first state, and

selects one of the first information and the first data on the basis of the address of the first block and writes the selected first information or first data to the first block.

A method of controlling a memory according to one aspect of the present invention includes:

reading first data from a first block of a non-volatile memory that includes a plurality of blocks of memory cells that enter into both a first state and a second state and in which a plurality of addresses is allocated to the plurality of blocks;

specifying the memory cell in the second state among the memory cells in the first block and writing second data for causing the specified memory cell in the second state to transition to the first state; and

selecting one of first information held in an information holding unit and the first data on the basis of the address of the first block and writing the selected first information or first data to the first block.

### BRIEF DESCRIPTION OF DRAWINGS

FIG. 1 shows an entire configuration example of a system according to a first embodiment.

FIG. 2 is a block diagram of a non-volatile memory (NVM).

FIG. 3 shows a configuration of a buffer.

FIG. 4 shows a configuration example of one tile.

FIG. 5 shows a configuration example of a memory cell.

FIG. 6 is a state transition diagram of a memory cell.

FIG. 7 shows an example of a relationship between an LRS, an HRS, a change of a resistance state, an overset state, an overreset state, and Vread.

FIG. 8 shows an operation flow of processing performed in a case where a request processing unit receives a program request.

FIG. 9 shows an operation flow of set processing.

FIG. 10 shows an example of data held in various buffers.

FIG. 11 shows an example of data held in various buffers.

FIG. 12 shows an operation flow of reset processing.

FIG. 13 shows an example of data held in various buffers.

FIG. 14 shows an example of data held in various buffers.

FIG. 15 shows an operation flow of processing of executing an LRS transition request.

FIG. 16 shows an operation flow of processing of executing a read request.

FIG. 17 shows a configuration example of a controller.

FIG. 18 shows an example of a logical-to-physical address conversion table.

FIG. 19 shows an example of an unused physical address list.

FIG. 20 shows an example of health information.

FIG. 21 shows a configuration example of a refresh control unit.

FIG. 22 shows an example of a refresh operation reference table.

FIG. 23 shows an operation flow of refresh processing executed by a controller.

FIG. 24 shows an operation flow of processing executed when a controller receives a read command.

FIG. 25 shows an operation flow of processing executed when a controller receives a write command.

FIG. 26 shows an operation flow of processing executed when a controller receives a read command of health information.

FIG. 27 shows an operation flow of refresh processing according to Modification Example 1.

FIG. 28 shows an operation flow of refresh processing according to Modification Example 2.

FIG. 29 shows an example of a refresh operation reference table according to Modification Example 3.

FIG. 30 shows an operation flow of refresh processing according to Modification Example 3.

### MODE FOR CARRYING OUT THE INVENTION

Hereinafter, embodiments of the present disclosure will be described with reference to the drawings. In one or more embodiments shown in the present disclosure, elements included in each embodiment can be combined with each other, and results of the combination also form a part of the embodiments shown in the present disclosure.

### First Embodiment

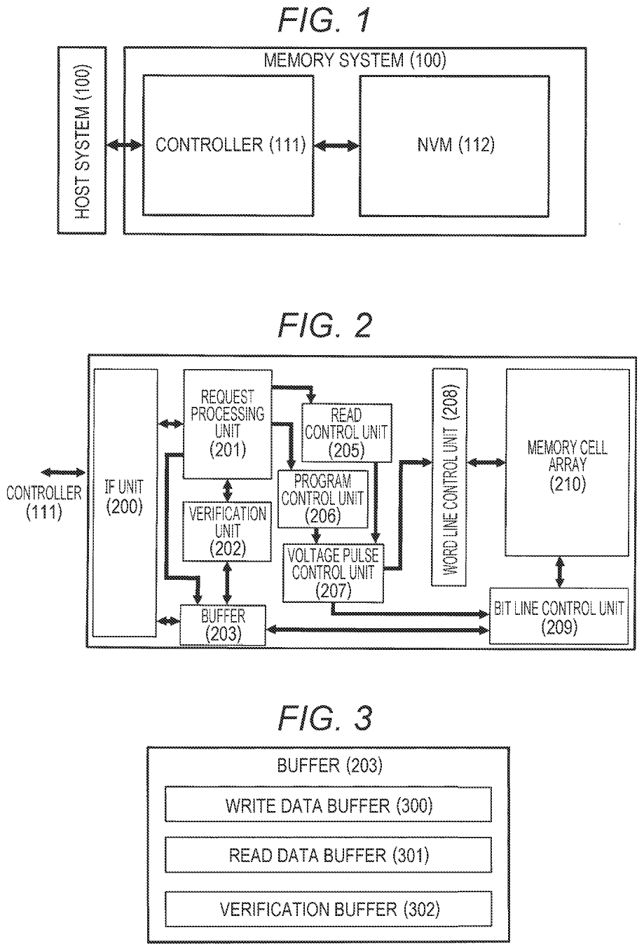

FIG. 1 shows an entire configuration example of a system according to a first embodiment. The system of FIG. 1 includes a host system 100 and a memory system 110.

The memory system 110 includes a controller 111 and a non-volatile memory (NVM) 112. The controller 111 communicates with the host system 100 and receives a write command or a read command from the host system 100. Further, the controller 111 writes data to the NVM 112 or reads data from the NVM 112 on the basis of the received command.

Upon receipt of a write command from the host system 100, the controller 111 further receives data to be written from the host system 100. The controller 111 issues a write request to the NVM 112 and transmits the data received from the host system 100 to the NVM 112. The NVM 112 writes the data received from the controller 111 to an internal memory cell array.

Upon receipt of a read command from the host system 100, the controller 111 issues a read request to the NVM 112 and reads data from the NVM 112. The controller 111 transmits the data read from the NVM 112 to the host system 100.

When generating a write command and a read command, the host system 100 designates a logical address as an address indicating a location of data to be written or read.

A block indicated by one logical address is, for example, 512 bytes in size. A range of logical addresses that can be designated by the host system 100 is, for example, 0x000000 to 0xDFFFFF (7 gigabytes in size).

Meanwhile, when generating a program request (write request) and a read request for the NVM 112, the controller 111 uses a physical address as the address indicating the location of the data.

A block indicated by one physical address is, for example, 525 bytes (4200 bits) in size. Among 525 bytes, 512 consecutive bytes from the head are the data to be written received from the host system, and the remaining 13 bytes are an error correction code (ECC). A range of physical addresses that can be designated by the controller 111 is, for example, 0x000000 to 0xFFFFFF (8 gigabytes in size).

[Description of NVM]

FIG. 2 is a block diagram of the NVM 112.

The NVM 112 includes an interface unit (IF unit) 200, a request processing unit 201, a verification unit 202, a buffer 203, a read control unit 205, a program control unit 206, a voltage pulse control unit 207, a word line control unit 208, a bit line control unit 209, and a memory cell array 210.

FIG. 3 shows a configuration of the buffer 203. The buffer 203 includes a write data buffer 300, a read data buffer 301, and a verification buffer 302. The write data buffer 300, the read data buffer 301, and the verification buffer 302 are, for example, 4200 bits (525 bytes) in size.

The interface unit 200 communicates with the controller 111. Upon receipt of a request from the controller 111, the interface unit 200 supplies the received request to the request processing unit 201. Examples of the types of the request include a write request (program request) and a read request. Further, upon receipt of data to be written from the controller 111, the interface unit 200 writes the data to the write data buffer 300 of the buffer 203.

Upon receipt of the request from the interface unit 200, the request processing unit 201 supplies an instruction according to the type of the request to the program control unit 206 or the read control unit 205. Specifically, in a case of the write request (program request), a write instruction is supplied to the program control unit 206, whereas, in a case of the read request, a read instruction is supplied to the read control unit 205.

The word line control unit 208 selects a word line from a plurality of word lines in the memory cell array 210 in response to a pulse from the voltage pulse control unit 207 and applies a voltage to the selected word line. The bit line control unit 209 selects a bit line from a plurality of bit lines in the memory cell array 210 in response to a pulse from the voltage pulse control unit 207 and applies a voltage to the selected bit line.

The read control unit 205 transmits a read instruction signal to the voltage pulse control unit 207 in response to the read instruction from the request processing unit 201. In response to the instruction from the read control unit 205, the voltage pulse control unit 207 applies a read pulse as a voltage to the memory cell array 210 via the word line control unit 208 and the bit line control unit 209.

The program control unit 206 transmits a set or reset instruction signal to the voltage pulse control unit 207 in response to the write instruction (a set instruction or a reset instruction described later) from the request processing unit 201. The voltage pulse control unit 207 applies a set pulse or a reset pulse as a voltage to the memory cell array 210 via the word line control unit 208 and the bit line control unit 209. As described later, in the present embodiment, the set means writing “1”, that is, causing a memory cell to transition to a low resistance state (LRS). The reset means writing “0”, that is, causing a memory cell to transition to a high resistance state (HRS). The read data buffer holds data read from the memory cell array 210. The verification buffer holds data in which a value of a bit corresponding to a memory cell to be subjected to the set is “1” and a value of a bit corresponding to a memory cell not required to be subjected to the set is “0”.

[Description of Memory Cell Array]

The memory cell array 210 includes a plurality of tiles. Each tile includes a plurality of memory cells.

In the present embodiment, the memory cell array 210 includes, for example, 4200 tiles. Each tile includes 4096×4096 memory cells.

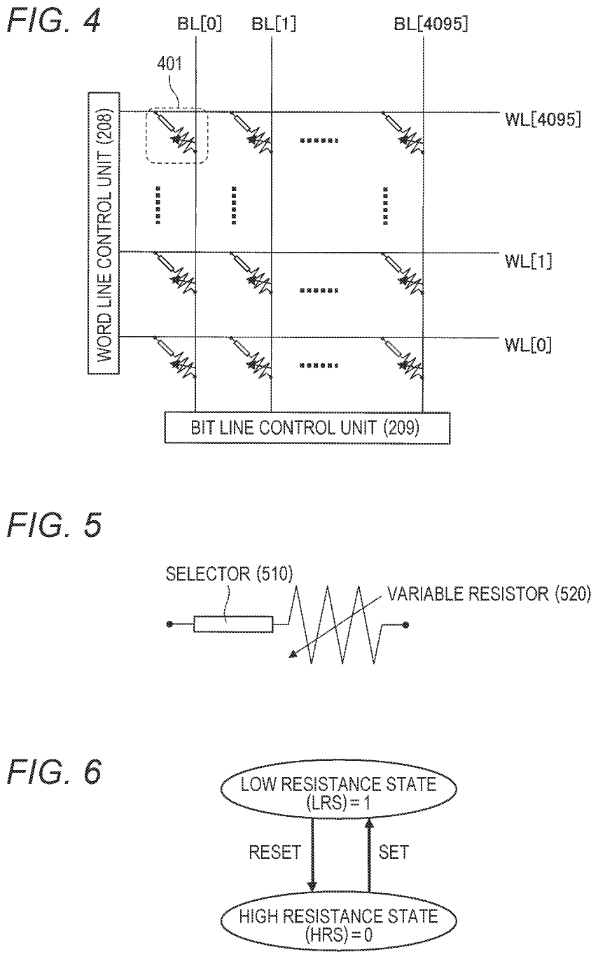

FIG. 4 shows a configuration example of one tile. Memory cells 401 are placed at intersections of 4096 bit lines and 4096 word lines. The memory cells 401 have a cross-point structure. The cross-point structure is a structure including memory cells at intersections of bit lines and word lines.

FIG. 5 shows a configuration example of the memory cell. The memory cell 401 includes a selector (switch) 510 and a variable resistor 520. The selector 510 and the variable resistor 520 are connected in series.

FIG. 6 is a state transition diagram of the memory cell. The variable resistor 520 has one of the low resistance state (LRS) and the high resistance state (HRS) that transition to each other. The variable resistor 520 has a rewrite life that is the number of possible state transitions. The selector 510 has a selector life that is the number of times the selector can be turned on (also referred to as snapped). The low resistance state (LRS) corresponds to, for example, a first state of the memory cell, and the high resistance state (HRS) corresponds to, for example, a second state of the memory cell. The memory cell enters into both the first state (LRS) and the second state (HRS). Further, for example, the first state (LRS) corresponds to a first value, and the second state (HRS) corresponds to a second value. The first value corresponds to “1” and the second value corresponds to “0”. Alternatively, the first value may correspond to “0” and the second value may correspond to “1”. In the present embodiment, it is assumed that the LRS corresponds to “1” and the HRS corresponds to “0”, but the present disclosure is not limited thereto.

When the selector 510 is not turned on for a long time, a threshold voltage Vsnap necessary to turn on the selector 510 increases (referred to as drift). When a voltage equal to or higher than the threshold voltage subjected to the drift is applied to the selector 510, the selector 510 is turned on. When the selector 510 is turned on, the drift is eliminated. Therefore, the threshold voltage subjected to the drift returns to a voltage of an initial value.

In order to read data from a memory cell 401, pulses of voltages of −Vread/2 and Vread/2 are applied to a word line and a bit line, respectively, connected to the selected memory cell 401. A read pulse of a predetermined read voltage Vread (=Vread/2−(−Vread/2)) is applied to the selected memory cell 401. On the basis of a current flowing through the memory cell 401, whether a resistance state of the variable resistor 520 is the LRS or the HRS is determined. In a case where the selector 510 is turned on, a current flows through the memory cell 401. In this case, it is determined that the resistance state of the variable resistor 520 is the LRS, and data of “1” is read. In a case where the selector 510 is not turned on, a current does not flow through the memory cell 401. In this case, it is determined that the resistance state of the variable resistor 520 is the HRS, and data of “0” is read.

In a case where the threshold voltage Vsnap is higher than the predetermined read voltage due to occurrence of the drift, the selector 510 is not turned on by the application of the predetermined read voltage even if the variable resistor 520 is in the LRS. Therefore, even if the resistance state of the variable resistor 520 is the LRS, a current necessary to determine the LRS does not flow. As a result, the state of the variable resistor 520 is erroneously determined as the HRS. That is, although the memory cell actually stores data of “1”, it is determined that the memory cell stores data of “0”.

In a case where data of “1” is written to a memory cell (referred to as set), pulses of voltages of −Vset/2 and Vset/2 are applied to a word line and a bit line, respectively, connected to the selected memory cell 401. A set pulse of a predetermined set voltage Vset (=Vset/2−(−Vset/2)) is applied to the selected memory cell 401. In a case where the resistance state of the variable resistor 520 is the HRS, the state transitions to the LRS. Therefore, data of “1” is written to the memory cell.

In a case where data of “0” is written to a memory cell (referred to as reset), pulses of voltages of Vreset/2 and −Vreset/2 are applied to a word line and a bit line, respectively, connected to the selected memory cell 401. A reset pulse of a predetermined reset voltage Vrset (=Vrset/2−(−Vrset/2)) is applied to the selected memory cell 401. A direction of the voltage of the reset pulse is opposite to a direction of the set pulse. In a case where the resistance state of the variable resistor 520 is the LRS, the state transitions to the HRS. Therefore, data of “0” is written to the memory cell.

Note that, when the reset pulse is applied to the memory cell 401 while the variable resistor 520 is in the HRS, the memory cell 401 enters into an overreset state. In the overreset state, the memory cell 401 does not transition to the LRS even if the set pulse is applied to the memory cell 401, and the memory cell 401 cannot normally store data. The memory cell 401 in the overreset state becomes a cell in a defective state (defective cell).

Similarly, when the set pulse is applied to the memory cell 401 while the variable resistor 520 is in the LRS state, the memory cell 401 enters into an overset state. In the overset state, the memory cell 401 does not transition to the HRS even if the reset pulse is applied, and the memory cell 401 cannot normally store data. The memory cell 401 in the overset state becomes a defective cell.

In order to keep the threshold voltage Vsnap equal to or lower than the predetermined read voltage Vread so that the selector 510 is turned on at the predetermined read voltage Vread, it is necessary to turn on the selector 510 periodically or at arbitrary intervals to eliminate the drift. When the selector 510 is turned on, the threshold voltage Vsnap returns to the voltage of the initial value lower than the predetermined read voltage. Therefore, the drift is eliminated.

The controller 111 performs refresh processing of the memory cells (refresh processing of the drift) periodically or at arbitrary intervals. The refresh processing includes an operation of turning on the selectors 510 of the memory cells, and therefore the drift can be eliminated. More specifically, in the refresh processing, data (1 or 0) is temporarily read from a target memory cell and is held. A read voltage at this time is equal to or higher than a voltage obtained by adding an amount of rise caused by the drift to the predetermined read voltage. The amount of rise caused by the drift can be calculated by acquiring correspondence information in which an elapsed time from a time at which the selector 510 has been turned on and a rising voltage of the drift are associated with each other in advance by measurement or simulation. Next, in a case where the resistance state of the memory cell is the HRS (in a case where the read data is 0), the variable resistor 520 of the memory cell in the HRS is caused to transition to the LRS (1 is written). The selector 510 is turned on at this time, and thus the drift is eliminated. Thereafter, processing of returning the held data to the memory cell is performed. That is, the held data 0 is written to the memory cell, and the variable resistor 520 is caused to transition to the HRS. Meanwhile, in a case where the resistance state of the memory cell is the LRS (in a case where the read data is 1), the selector 510 is on at the time when the data is read. Thus, there is no need to perform the processing of causing the memory cell to transition to the LRS and the processing of writing back the read data. In the memory cell of the present embodiment, it is assumed that the drift is eliminated by turning on the selector 510 again within 10,000 [s] after turning on the selector 510, and the threshold voltage Vsnap risen by the drift returns to the initial voltage.

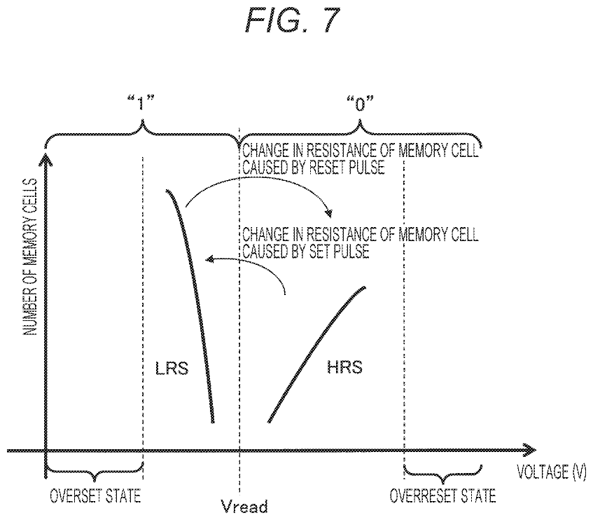

FIG. 7 shows an example of a relationship between the LRS, the HRS, a change of the resistance state, the overset state, the overreset state, and Vread. The horizontal axis represents the voltage, and the vertical axis represents the number of cumulative memory cells. A graph of the LRS and a graph of the HRS show a cumulative distribution of the number of memory cells in the LRS and a cumulative distribution of the number of memory cells in the HRS, respectively. The graphs show, for example, states at a certain point of time.

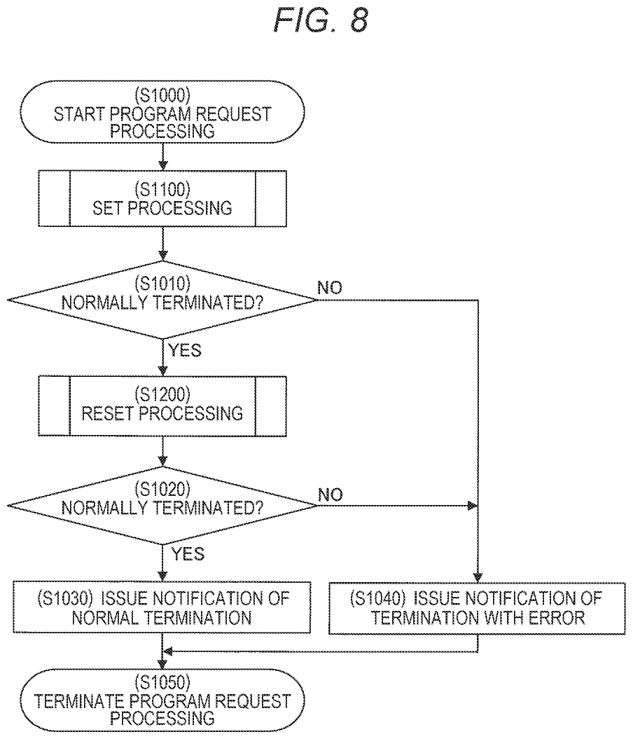

FIG. 8 shows an operation flow of processing performed in a case where the request processing unit 201 receives a program request (write request).

(S1000)

Upon receipt of a program request and a physical address to be written from the controller 111 via the interface unit 200, the request processing unit 201 starts program request processing in S1000. A block (area) indicated by one physical address includes a plurality of memory cells (e.g., memory cells corresponding to 525 bytes). Data of 4200 bits (525 bytes) necessary for the program request processing is transmitted from the interface unit 200 to the write data buffer 300 and is held in the write data buffer 300. Bits of bit strings of 525 bytes stored in the write data buffer 300 are associated with the plurality of memory cells in the block designated by the physical address on a one-to-one basis. A memory cell corresponding to a bit of “1” in the bit strings is a memory cell to enter into the LRS. The physical address is transferred from the interface unit 200 to the request processing unit 201 and is held in the request processing unit 201.

(S1100)

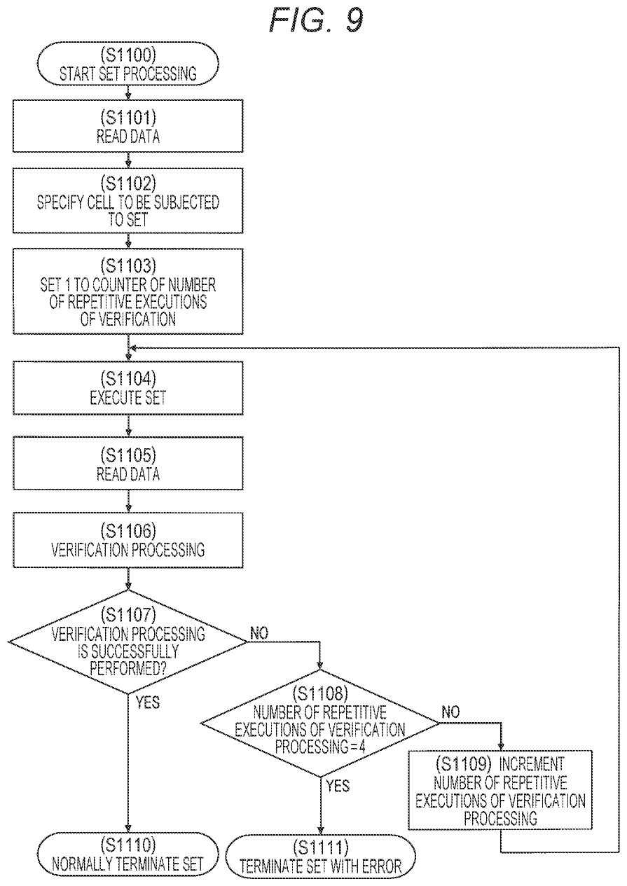

The request processing unit 201 executes set processing. In the set processing, a memory cell to which 1 is to be written is specified, and 1 is written to the specified memory cell. Specifically, a memory cell whose current resistance state is the HRS(0) is specified among the memory cells whose resistance state is 1 in the write data buffer 300. This is because there is no need to write 1 to a memory cell to which 1 has already been written (a memory cell whose current resistance state is the LRS). An operation flow of the set processing is shown in FIG. 9 described later.

(S1010)

The request processing unit 201 determines whether or not the set processing executed in step S1100 has been normally terminated. In a case where the set processing has been normally terminated, the processing proceeds to step S1200. In a case where the set processing has been terminated with an error, the processing proceeds to step S1040.

(S1200)

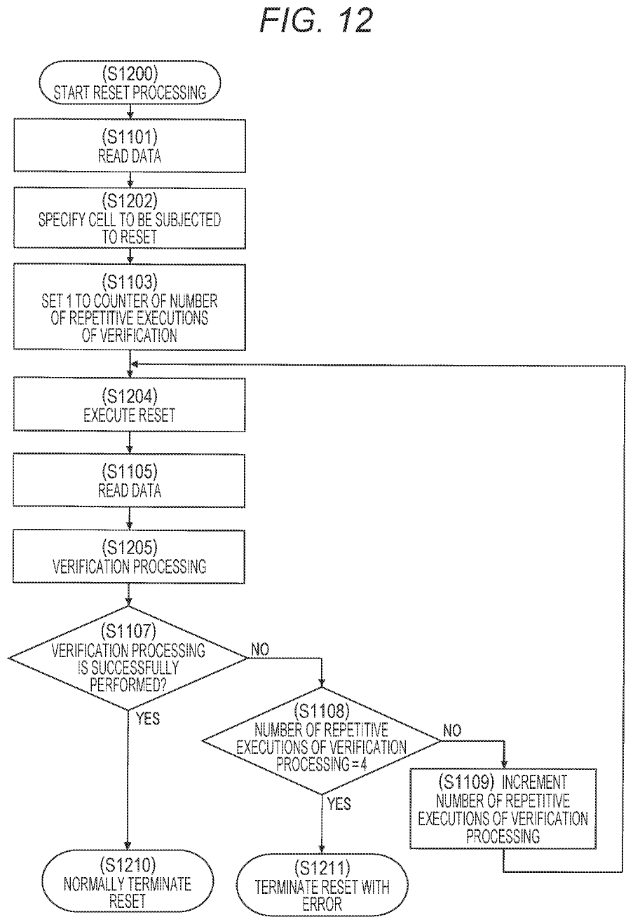

The request processing unit 201 executes reset processing. In the reset processing, a memory cell to which 0 is to be written is specified, and 0 is written to the specified memory cell. Specifically, a memory cell whose current resistance state is the LRS (1) is specified among the memory cells whose resistance state is 0 in the write data buffer 300. This is because there is no need to write 0 to a memory cell to which 0 has already been written (a memory cell whose current resistance state is the HRS). An operation flow of the reset processing is shown in FIG. 12 described later.

(S1020)

The request processing unit 201 determines whether or not the reset processing executed in step S1200 has been normally terminated. In a case where the reset processing has been normally terminated, the processing proceeds to step S1030. In a case where the reset processing has been terminated with an error, the processing proceeds to step S1040.

(S1030)

The request processing unit 201 notifies the controller 111 via the interface unit 200 that the program request processing has been normally terminated.

(S1040)

The request processing unit 201 notifies the controller 111 via the interface unit 200 that an error has occurred in the program request processing.

(S1050)

After step 1321 or S1040, the program request processing is terminated.

[Description of Set Processing]

FIG. 9 shows the operation flow of the set processing executed in step S1100 of FIG. 8. A data size handled in the set processing is, for example, 4200 bits (525 bytes).

(S1101)

The request processing unit 201 designates the physical address received from the controller 111 with respect to the read control unit 205 and instructs the read control unit 205 to read 4200 bits (525 bytes). The read control unit 205 reads data from the memory cell array 210 via the voltage pulse control unit 207. The read data is transmitted to the read data buffer 301 and is held in the read data buffer 301.

(S1102)

The request processing unit 201 instructs the verification unit 202 to compare the data held in the read data buffer 301 with the data held in the write data buffer 300. The verification 302 unit compares the data held in the read data buffer 301 with the data held in the write data buffer 300 in units of bits. Therefore, a memory cell to which the set pulse is to be applied (a memory cell to which 1 is to be written) is specified.

The memory cell to which the set pulse is to be applied is a memory cell whose value held in the write data buffer 300 is “1” and whose value held in the read data buffer 301 is “0”. This memory cell needs to change the resistance state of the memory cell corresponding to a bit from the HRS to the LRS.

The verification unit 202 generates data in which a value of a bit corresponding to the memory cell to which the set pulse needs to be applied is “1” and a value of a bit corresponding to a memory cell to which the set pulse does not need to be applied is “0”. The generated data is held in the verification buffer 302. This data corresponds to information for specifying a memory cell to which the set pulse is to be applied.

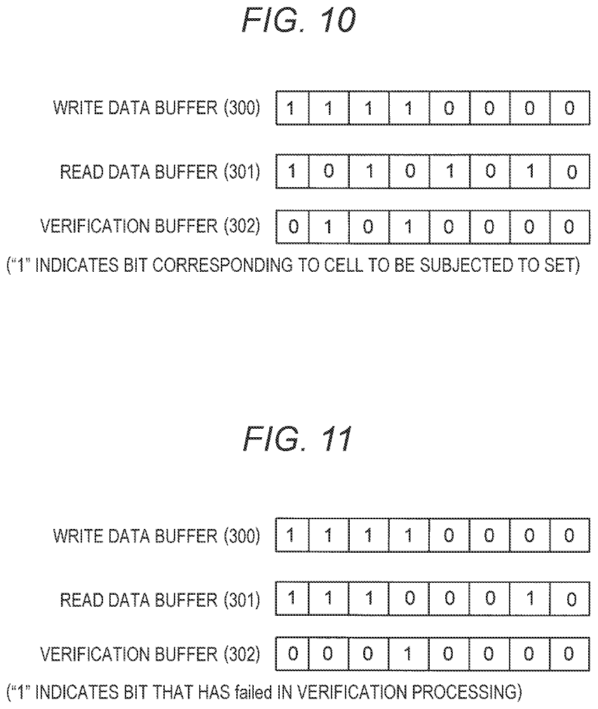

FIG. 10 shows an example of the data held in the write data buffer 300, the read data buffer 301, and the verification buffer 302. FIG. 10 shows, as a simple example, an example of specifying a cell to be subjected to the set processing by using 8-bit data. That is, 8 bits correspond to memory cells on a one-to-one basis, and memory cells of 1 in the verification buffer 302 are memory cells to which the set pulse is to be applied.

(S1103)

The request processing unit 201 sets a value of a counter provided inside the request processing unit 201 to 1. The counter indicates the number of repetitive executions of verification processing performed in step S1106 described later.

(S1104)

The request processing unit 201 instructs the program control unit 206 to apply the set pulse to the memory cells whose bit is 1 in the data held in the verification buffer 302. The program control unit 206 performs control to apply the set pulse to the memory cells, thereby performing processing of causing the resistance state of the memory cells to transition to the LRS.

(S1105)

The request processing unit 201 designates the physical address designated by the controller 111 with respect to the read control unit 205 and instructs the read control unit 205 to read data of 4200 bits (525 bytes). The read control unit 205 reads data from the memory cell array 210 via the voltage pulse control unit 207. The read data is transmitted to the read data buffer 301 and is held in the read data buffer 301.

(S1106)

The request processing unit 201 instructs the verification unit 202 to compare the data held in the read data buffer 301 in step S1105 with the data held in the write data buffer 300. The verification unit 202 compares both the data with each other. A bit to be compared is a bit whose value held in the write data buffer 300 is “1”. A bit whose value held in the write data buffer 300 is “1” and whose value held in the read data buffer 301 is “0” is a bit that has failed in the set (fail). A bit whose data value held in the write data buffer 300 is “1” and whose value held in the read data buffer 301 is also “1” is a bit that has succeeded in the set (pass). Such processing of determining whether or not the set (or reset) has been successfully performed on a bit to be compared is referred to as the verification processing.

The verification unit 202 generates data in which “1” is set to a failure bit, “0” is set to a success bit, and “0” is set to a bit other than bits to be compared. The generated data is held in the verification buffer 302.

FIG. 11 shows an example of the data held in the write data buffer 300, the read data buffer 301, and the verification buffer 302 subjected to the verification processing.

(S1107)

In a case where all the bits are “0” in the data held in the verification buffer 302, the verification unit 202 notifies the request processing unit 201 that the set processing has been normally terminated, and the processing proceeds to step S1110. Meanwhile, in a case where at least one bit in the data held in the verification buffer 302 is “1”, the processing proceeds to step S1108.

(S1110)

The request processing unit 201 normally terminates the set processing.

(S1108)

The number of repetitions of how many times the verification processing in step S1107 has been performed is determined on the basis of the value of the counter in the request processing unit 201. In a case where the number of repetitions has not reached an upper limit value (e.g., four), the processing proceeds to step S1109. Meanwhile, in a case where the number of repetitions has reached the upper limit value, the verification unit 202 notifies the request processing unit 201 that the set processing has failed, and the processing proceeds to step S1111.

(S1109)

The value of the counter is incremented by 1, and the processing returns to step S1104. In step S1104, the set is executed again. In this case, a memory cell to which the pulse is to be applied is a memory cell corresponding to a bit whose value of “1” is held in the verification buffer.

(S1111)

The request processing unit 201 terminates the set processing with an error.

[Description of Reset Processing]

FIG. 12 shows the operation flow of the reset processing executed in step S1200 of FIG. 8. Steps of the processing in FIG. 12 similar to those in FIG. 8 are denoted by the same reference numerals. A data size handled in the reset processing is, for example, 4200 bits (525 bytes). Data held in the write data buffer 300 is the same as the data used in the set processing in S1100. Further, a physical address is also the same as that in the set processing in S1100.

(S1101)

The request processing unit 201 designates the physical address received from the controller 111 with respect to the read control unit 205 and instructs the read control unit 205 to read 4200 bits (525 bytes). The read control unit 205 reads data from the memory cell array 210 via the voltage pulse control unit 207. The read data is transmitted to the read data buffer 301 and is held in the read data buffer 301.

(S1202)

The request processing unit 201 instructs the verification unit 202 to compare the data held in the read data buffer 301 in step S1101 with the data held in the write data buffer 300. The verification 302 unit compares the data held in the read data buffer 301 with the data held in the write data buffer 300 in units of bits. Therefore, a memory cell to which the reset pulse is to be applied (a memory cell to which 0 is to be written) is specified. The memory cell to which the reset pulse is to be applied is a memory cell whose value held in the write data buffer 300 is “0” and whose data value held in the read data buffer 301 is “1”. This memory cell needs to change the resistance state from the LRS to the HRS.

The verification unit 202 generates data in which a value of a bit corresponding to the memory cell to which the reset pulse needs to be applied is “1” and a value of a bit corresponding to a memory cell to which the reset pulse does not need to be applied is “0”. The generated data is held in the verification buffer 302. This data corresponds to information for specifying a memory cell to which the reset pulse is to be applied.

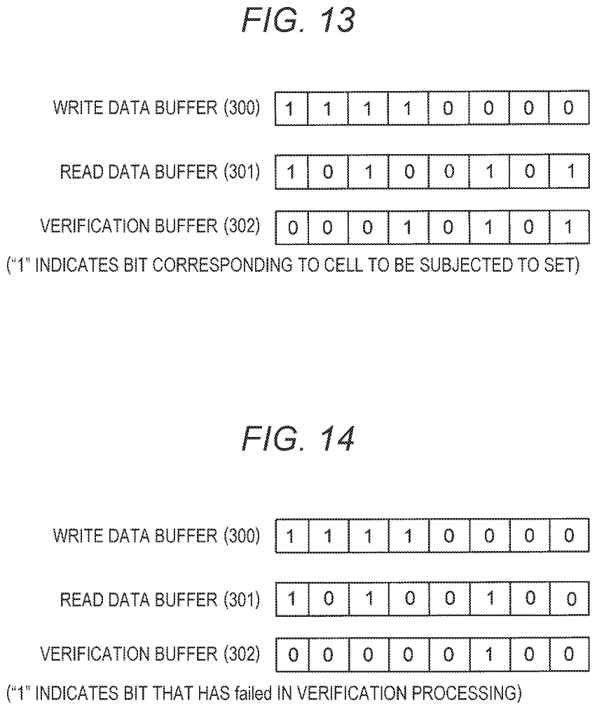

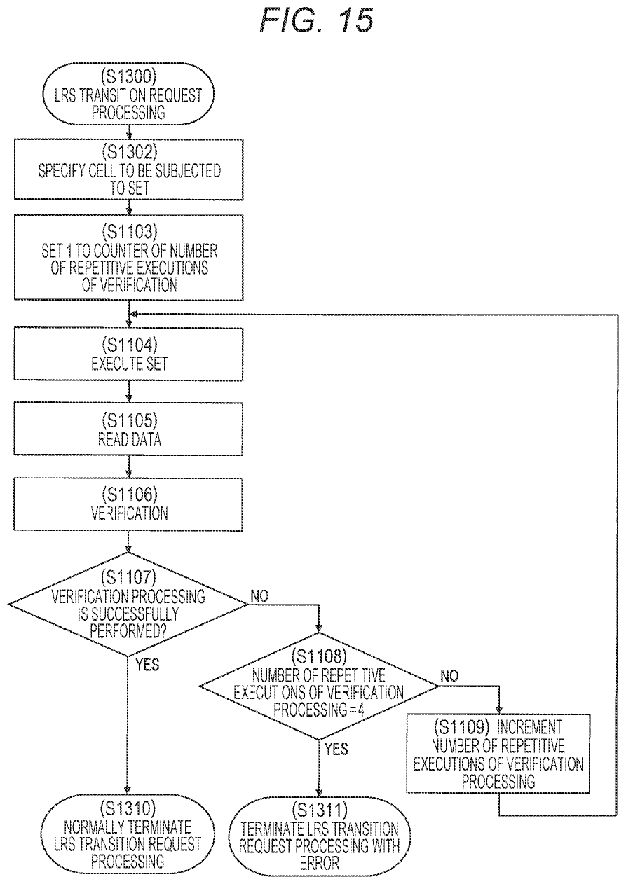

FIG. 13 shows an example of the data held in the write data buffer 300, the read data buffer 301, and the verification buffer 302. FIG. 13 shows, as a simple example, an example of specifying a cell to be subjected to the reset processing by using 8-bit data. That is, 8 bits correspond to memory cells on a one-to-one basis, and memory cells of 1 in the verification buffer 302 are memory cells to which the reset pulse is to be applied.

(S1204)

The request processing unit 201 instructs the program control unit 206 to apply the reset pulse to the memory cells whose bit is 1 in the data held in the verification buffer 302. The program control unit 206 performs control to apply the reset pulse to the memory cells, thereby performing processing of causing the resistance state of the memory cells to transition to the HRS.

(S1105)

The request processing unit 201 designates the physical address designated by the controller 111 with respect to the read control unit 205 and instructs the read control unit 205 to read data of 4200 bits (525 bytes). The read control unit 205 reads data from the memory cell array 210 via the voltage pulse control unit 207. The read data is transmitted to the read data buffer 301 and is held in the read data buffer 301.

(S1205)

The request processing unit 201 instructs the verification unit 202 to compare the data held in the read data buffer 301 in step S1105 with the data held in the write data buffer 300. The verification unit 202 performs the verification processing by comparing both the data with each other. A bit to be compared is a bit whose value held in the write data buffer 300 is “0”. A bit whose value held in the write data buffer 300 is “0” and whose value held in the read data buffer 301 is “1” is a bit that has failed in the reset (fail). A bit whose value held in the write data buffer 300 is “0” and whose value held in the read data buffer 301 is also “0” is a bit that has succeeded in the reset (pass).

The verification unit 202 generates data in which “1” is set to a failure bit, “0” is set to a success bit, and “0” is set to a bit other than bits to be compared. The generated data is held in the verification buffer 302.

FIG. 14 shows an example of the data held in the write data buffer 300, the read data buffer 301, and the verification buffer 302 subjected to the verification processing.

(S1107)

In a case where all the bits are “0” in the data held in the verification buffer 302, the verification unit 202 notifies the request processing unit 201 that the reset processing has been normally terminated, and the processing proceeds to step S1210. Meanwhile, in a case where at least one bit in the data held in the verification buffer 302 is “1”, the processing proceeds to step S1108.

(S1210)

The request processing unit 201 normally terminates the reset processing.

(S1108)

The number of repetitions of how many times the verification processing in step S1107 has been performed is determined on the basis of the value of the counter in the request processing unit 201. In a case where the number of repetitions has not reached an upper limit value (e.g., four), the processing proceeds to step S1109. Meanwhile, in a case where the number of repetitions has reached the upper limit value, the verification unit 202 notifies the request processing unit 201 that the reset processing has failed, and the processing proceeds to step S1211.

(S1109)

The value of the counter is incremented by 1, and the processing returns to step S1104. In step S1104, the reset is executed again. In this case, a memory cell to which the pulse is to be applied is a memory cell holding “1” in the verification buffer.

(S1211)

The request processing unit 201 terminates the reset processing with an error.

[Description of LRS Transition Request Processing]

FIG. 15 shows an operation flow of processing of executing an LRS transition request received from the controller 111. The LRS transition request is a request for processing of causing a resistance state of a designated memory cell to transition from the HRS to the LRS. This processing is used in the refresh processing described later. The processing in FIG. 15 is substantially the same as the set processing described with reference to FIG. 9, and therefore the same steps as those in FIG. 9 are denoted by the same reference numerals, and the same description will be omitted. FIG. 15 is different from FIG. 9 in that step S1101 (reading data) in FIG. 9 does not exist and step S1102 is replaced with step S1302.

(S1300)

Upon receipt of an LRS transition request and a physical address from the controller 111 via the interface unit 200, the request processing unit 201 starts LRS transition request processing in S1300. Data of 4200 bits (525 bytes) necessary for the LRS transition request processing is transmitted to the write data buffer 300 via the interface unit 200 and is held in the write data buffer 300. Further, the physical address to be subjected to the LRS transition is transmitted to the request processing unit 201 via the interface unit 200 and is held in the request processing unit 201. The physical address to be subjected to the LRS transition corresponds to, for example, an address of a first block. The data necessary for the LRS transition request processing corresponds to, for example, second data for causing a memory cell in the second state (HRS) among memory cells in the first block to transition to the first state (LRS).

(S1302)

The request processing unit 201 specifies a memory cell corresponding to a bit having a value of “1” in the data held in the write data buffer 300 as a memory cell to which the set pulse is to be applied. The request processing unit 201 generates data in which a value of a bit corresponding to the memory cell to which the set pulse needs to be applied is “1” and a value of a bit corresponding to a memory cell to which the set pulse does not need to be applied is “0”. The generated data is held in the verification buffer 302. This data corresponds to information regarding a memory cell to which the set pulse is to be applied (memory cell to be subjected to the LRS transition).

The subsequent steps are similar to those in FIG. 9, and thus the description thereof will be omitted.

[Description of Read Request Processing]

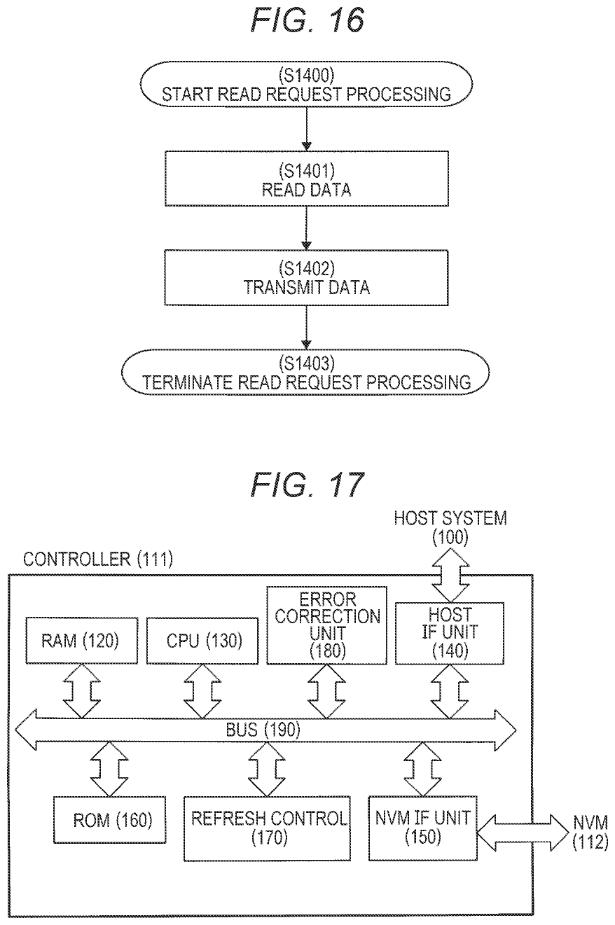

FIG. 16 shows an operation flow of processing of executing a read request received from the controller 111.

Upon receipt of a read request and a physical address to be read from the controller 111 via the interface unit 200, the request processing unit 201 starts execution of the read request in step S1400. The physical address is transmitted to the request processing unit 201 via the interface unit 200 and is held in the request processing unit 201. In the read request processing, data of 4200 bits (525 bytes) is read from a block indicated by the physical address in the memory cell array 210, and the read data is transmitted to the controller 111.

(S1401)

The request processing unit 201 designates the physical address designated by the controller 111 with respect to the read control unit 205 and instructs the read control unit 205 to read data of 4200 bits (525 bytes). The read control unit 205 reads data from the memory cell array 210 via the voltage pulse control unit 207. The read data is transmitted to the read data buffer 301 and is held in the read data buffer 301.

(S1402)

The request processing unit 201 transmits the data of 4200 bits (525 bytes) held in the read data buffer 301 to the controller 111 via the interface unit 200.

(S1403)

After step S1402, the read request processing is terminated.

[Description of Configuration of Controller]

FIG. 17 shows a configuration example of the controller 111. The controller 111 includes a RAM 120, a CPU 130, a host interface unit 140, an NVM interface unit 150, a ROM 160, a refresh control unit 170, and an error correction unit 180, and those elements are connected to each other via a bus 190. The NVM interface unit 150 corresponds to, for example, a first interface unit. The host interface unit 140 corresponds to, for example, a second interface unit. The CPU 130 corresponds to a control unit that controls, for example, write to and read from the NVM 112. The RAM 120 corresponds to an information holding unit that holds information or data.

The NVM interface unit 150 communicates with the NVM 112. For example, the NVM interface unit 150 transmits a request (write request or read request) to be executed by the NVM 112 to the NVM 112. Further, in a case of transmitting the write request, the NVM interface unit 150 transmits data to be written to the NVM 112. Meanwhile, in a case of transmitting the read request, the NVM interface unit 150 receives data read from the NMV 112.

The host interface unit 140 communicates with the host system 100. For example, the host interface unit 140 receives a command (write command or read command) from the host system 100. Further, the host interface unit 140 receives data to be written indicated by the write command from the host system 100. The host interface unit 140 transmits data read from the NVM 112 to the host system 100 in response to the read command.

The error correction unit 180 calculates an error correction code (ECC) of data to be written to the NVM 112. Data obtained by combining the calculated ECC with the data is actually written to the NVM 112. Further, the error correction unit 180 executes error correction of data read from the NVM 112 on the basis of an ECC included in the read data. The error correction unit 180 has, for example, a capability of correcting 8 bits. The ECC is, for example, 13 bytes in size.

The ROM 160 stores software for controlling the memory system 110 (see FIG. 1).

The CPU 130 executes the software stored in the ROM 160 by using the RAM 120 as a working memory.

The RAM 120 is a volatile memory. The RAM 120 is used not only as a working memory of the CPU 130 but also for holding information or data for managing the NVM 112. Further, the RAM 120 is also used for temporarily holding data transferred between the host system 100 and the controller 111 and for temporarily holding data transferred between the controller 111 and the NVM 112.

Further, the RAM 120 holds a logical-to-physical address conversion table 500, an unused physical address list 600, and health information 700.

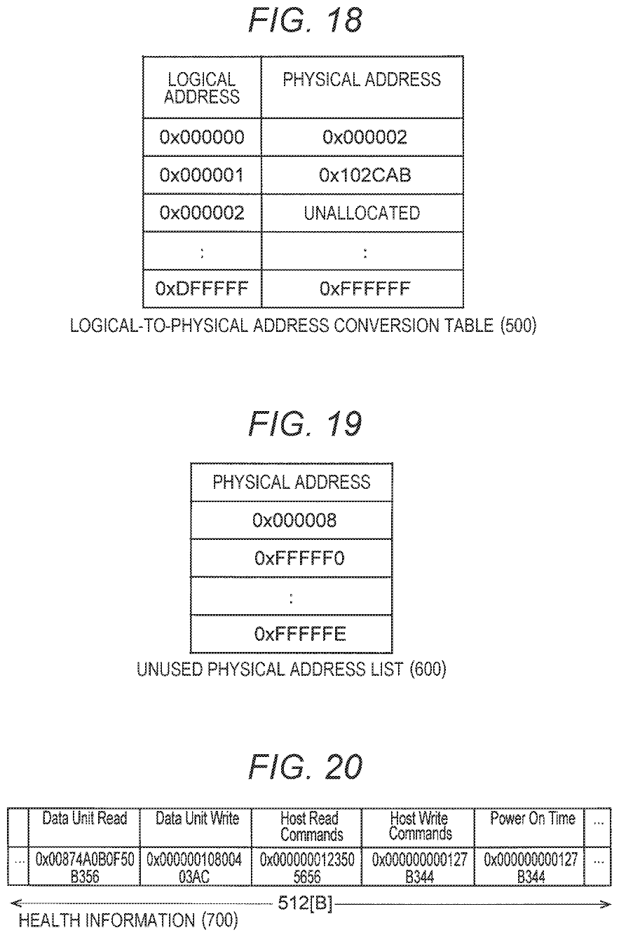

FIG. 18 shows an example of the logical-to-physical address conversion table 500. The logical-to-physical address conversion table 500 associates a logical address designated by the host system 100 with a physical address of the NVM 112. Information indicating “unallocated” is stored for a logical address with which no physical address is associated. A bit depth of the logical address and a bit depth of the physical address are assumed to be the same, but it is not excluded that the bit depth of the logical address and the bit depth of the physical address are different.

FIG. 19 shows an example of the unused physical address list 600. The unused physical address list 600 stores information regarding physical addresses that are not allocated to logical addresses. The physical addresses in the unused physical address list 600 can be newly allocated to logical addresses.

FIG. 20 shows an example of the health information 700. The health information 700 indicates a health state of the memory system 110. The health information 700 is used to present the health state of the memory system 110 to the host. The health information 700 is, for example, self-monitoring analysis and reporting technology (SMART) information. The health information 700 is an example of information managed by the controller, such as information indicating the state of the memory system 110, and information other than the health information may be defined as first information of the present embodiment as long as the information is managed by the controller.

The health information 700 of FIG. 20 includes the number of reads (Data Unit Read), the number of writes (Data Unit Write), the number of executions of a read command (Host Read Commands), the number of executions of a write command (Host Write Commands), and an operating time (Power On Time).

The number of reads indicates a cumulative value of the number of reads of data of a unit size (e.g., 512 bytes), that is, a cumulative value of the number of executions of a read request.

The number of writes indicates a cumulative value of the number of writes of data of a unit size (e.g., 512 bytes), that is, a cumulative value of the number of executions of a write request.

The number of executions of a read command indicates a cumulative value of the number of receptions of a read command from the host system 100 or a cumulative value of the number of executions thereof.

The number of executions of a read command indicates a cumulative value of the number of receptions of a write command from the host system 100 or a cumulative value of the number of executions thereof.

The operating time indicates a time during which the memory system 110 continuously operates after a power supply is turned on.

The refresh control unit 170 controls the refresh processing of refreshing memory cells of one physical address at regular time intervals in cooperation with the CPU 130. For example, in a case where the selectors 510 of the memory cells of all the physical addresses (0x000000-0xFFFFFF) in the NVM 112 need to be turned on (snapped) within 10,000 [s] in view of characteristics of the NVM 112, a time interval for the refresh is 596 [us]. The time interval is 596 [us] in this example.

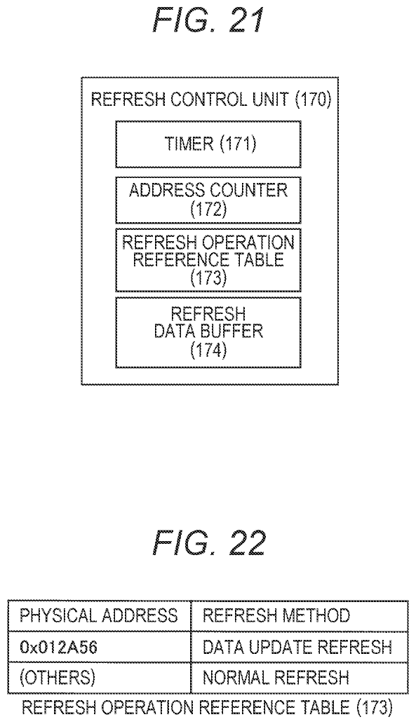

FIG. 21 shows a configuration example of the refresh control unit 170. The refresh control unit 170 includes a timer 171, an address counter 172, a refresh operation reference table 173, and a refresh data buffer 174.

A refresh time interval is set in the timer 171. The timer 171 outputs an interrupt signal to the CPU 130 at the set time intervals. For example, in a case where 596 [us] is set, the interrupt signal is output from the timer 171 to the CPU 130 every 596 [us]. The interrupt signal serves as a trigger signal for the refresh processing.

The address counter 172 presents a value of a physical address to be refreshed. The address counter 172 increments a value in response to an instruction signal from the CPU 130. By repeating the increment, the address counter 172 sequentially presents all the physical addresses to be refreshed to the CPU 130.

The refresh operation reference table 173 has information indicating a refresh method for each physical address.

FIG. 22 shows an example of the refresh operation reference table 173. The refresh method includes data update refresh and normal refresh. In the normal refresh, data read from the physical address to be refreshed is subjected to error correction, and the data subjected to the error correction is written back. Note that, in some cases, the data read from the physical address to be refreshed is written back without being subjected to error correction. In the data update refresh, the first information different from the data read from the physical address to be refreshed is written to the physical address to be refreshed. In the present embodiment, health information (latest health information) in the RAM 120 is written as the first information to be written in the data update refresh. In the example of FIG. 22, the data update refresh is designated for “0x012A56”, and the normal refresh is designated for all the other physical addresses.

The refresh data buffer 174 is a buffer that holds data read from the NVM 112. Alternatively, the refresh data buffer 174 holds data obtained by performing error correction on the data read from the NVM 112 on the basis of an ECC included in the data.

[Description of Refresh Processing]

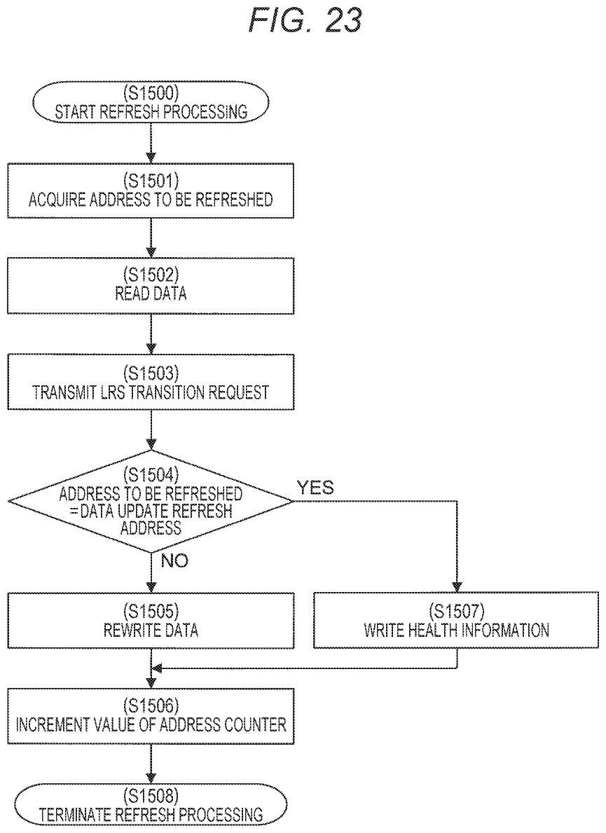

FIG. 23 shows an operation flow of the refresh processing executed by the controller 111. When an interrupt signal is input to the CPU 130 from the timer 171, the refresh processing is started. At the start of the refresh processing, the CPU 130 counts up the value of the Power On Time of the health information 700 in accordance with an elapsed time from a previous update.

(S1501)

The CPU 130 acquires a value of the address counter 172 of the refresh control unit 170 as an address to be refreshed.

(S1502)

The CPU 130 designates the address to be refreshed with respect to the NVM 112 and issues a read request to the NVM 112. According to the operation flow of FIG. 16 described above, data is read from a plurality of memory cells belonging to the address to be refreshed (i.e., a plurality of memory cells included in a block indicated by the address to be refreshed) in the memory cell array 210 of the NVM 112. The CPU 130 corrects an error of the data read from the NVM 112 by using the error correction unit 180. The CPU 130 stores the corrected data in the refresh data buffer 174 of the refresh control unit 170. The data read from the NVM 112 or the corrected data corresponds to, for example, first data read from the first block.

(S1503)

The CPU 130 designates the address to be refreshed with respect to the NVM 112 and issues an LRS transition request to the NVM 112. The CPU 130 reads the data from the refresh data buffer 174. The CPU 130 can specify whether the memory cell corresponding to each bit is in the HRS or the LRS on the basis of the read data. It is possible to specify that the memory cell corresponding to a bit of “1” is in the HRS and the memory cell corresponding to a bit of “0” is in the LRS. The CPU 130 inverts the read data. In the inverted data, the memory cell corresponding to the bit of “1” is a memory cell to transition to the LRS. This memory cell is a memory cell whose current resistance state is the HRS (memory cell to which 0 is written) and is also a memory cell whose selector 510 has not been turned on by the reading in S1502. The CPU 130 transmits the inverted data to the NVM 112 (note that the data in the refresh data buffer 174 cannot be inverted). An operation flow of the NVM 112 that has received the LRS transition request is shown in FIG. 15 described above. The inverted data corresponds to, for example, the second data for causing a memory cell in the second state (HRS) among memory cells in the first block to transition to the first state (LRS).

(S1504)

The CPU 130 selects one of the data held in the refresh data buffer 174 and the health information on the basis of the address to be refreshed and writes the selected one to the plurality of memory cells of the address to be refreshed. More specifically, the CPU 130 first refers to the refresh operation reference table 173 and determines whether or not the address to be refreshed corresponds to a data update refresh address. The data update refresh address corresponds to, for example, a first address.

(S1505)

In a case where the address to be refreshed does not correspond to the data update refresh address, the CPU 130 designates the address to be refreshed and transmits a program request (write request) to the NVM 112. Further, the CPU 130 transmits the data held in the refresh data buffer 174. The transmitted data is written to the plurality of memory cells belonging to the address to be refreshed in the memory cell array 210 of the NVM 112 in accordance with the operation flow of FIG. 8 described above. In a case where the address to be refreshed does not correspond to the data update refresh address as described above, the CPU 130 selects the data held in the refresh data buffer 174 and writes the selected data to the address to be refreshed.

(S1507)

In a case where the address to be refreshed corresponds to the data update refresh address, the CPU 130 designates the address to be refreshed with respect to the NVM 112 and transmits a program request (write request) to the NVM 112. Further, the CPU 130 generates data by adding an ECC calculated by the error correction unit 180 to the health information stored in the RAM 120 as data to be written and transmits the generated data. The health information or the data obtained by adding the ECC to the health information corresponds to, for example, the first information. The data obtained by adding the ECC is written to the plurality of memory cells belonging to the address to be refreshed in the memory cell array 210 of the NVM 112 in accordance with the operation flow of FIG. 8 described above. In a case where the address to be refreshed corresponds to the data update refresh address as described above, the CPU 130 selects the health information (first information) and writes the selected health information to the address to be refreshed.

(S1506)

The CPU 130 transmits an instruction signal to the refresh control unit 170 so as to increment the value of the address counter 172 (the value of the address to be refreshed). The refresh control unit 170 updates the value of the address counter 172 in response to the instruction signal from the CPU 130.

(S1508)

After step S1506, the refresh processing of one physical address is terminated.

[Description of Read Command Processing]

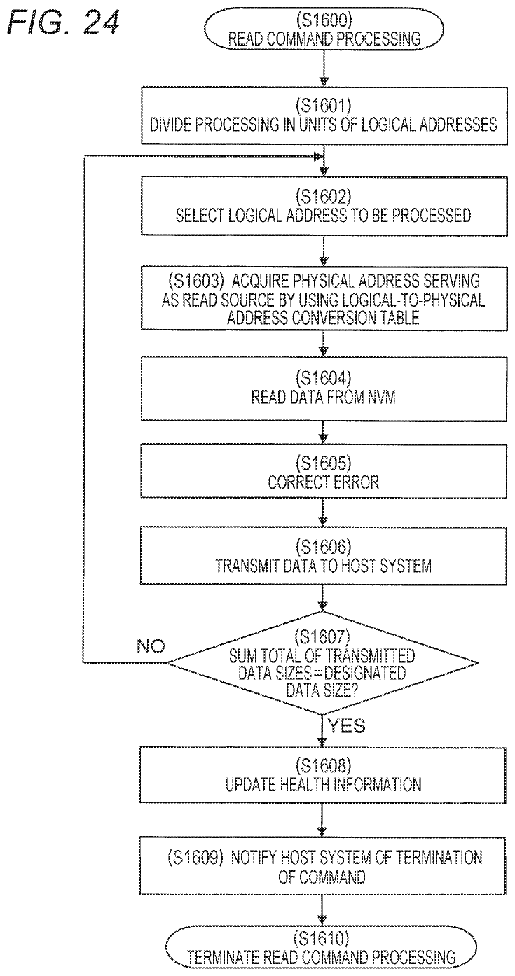

FIG. 24 shows an operation flow of processing executed when the controller 111 receives a read command from the host system 100.

(S1600)

When receiving a read command together with information regarding a head logical address to be read and a data size via the host interface unit 140, the CPU 130 starts read command processing.

(S1601)

The CPU 130 divides read processing in units of logical addresses (in units of logical pages). One logical address is executed in one-time processing. For example, in a case where “0” is designated as a head address to be read and “1” is designated as the data size, one-time processing is performed. Further, in a case where “0” is designated as the head logical address to be read and “2” is designated as the data size, the read processing is divided into two processes. The data size “1” represents an amount of data of one unit, and, for example, “1” is 512 bytes.

(S1602)

The CPU 130 determines logical addresses to be read. The logical addresses to be read are determined in order from the head logical address to be read. In a case where “0” is designated as the head address to be read and “2” is designated as the data size, a logical address to be subjected to the processing first is determined as “0”. A logical address to be subjected to the processing next is determined as “1”.

(S1603)

The CPU 130 converts the logical address determined as the address to be read into a physical address by using the logical-to-physical address conversion table 500 held in the RAM 120.

(S1604)

The CPU 130 designates the physical address converted in step S1603 with respect to the NVM 112 and transmits a read request to the NVM 112. Data read from the NVM 112 is, for example, 4200 bits (525 bytes) including an ECC.

(S1605)

The data of 4200 bits (525 bytes) read from the NVM 112 is transmitted to the error correction unit 180. The error correction unit 180 performs error correction by using the ECC included in the data of 4200 bits (525 bytes).

(S1606)

The CPU 130 transmits data of 512 bytes obtained by removing the ECC of 13 bytes from the data subjected to the error correction in the error correction unit 180 to the host system 100 via the host interface unit 140.

(S1607)

The CPU 130 determines whether or not the sum total of data sizes transmitted so far to the host system 100 matches the data size designated by the read command. In a case where the sum total of the data sizes transmitted to the host system 100 matches the data size designated by the read command, the processing proceeds to step S1608. In a case where the sum total of the data sizes does not match the data size, the processing returns to step S1602.

(S1608)

The CPU 130 updates the number of reads (Data Unit Read) and the number of executions of the read command (Host Read Commands) of the health information 700 held in the RAM 120. Specifically, a value obtained by dividing the sum total [B] of the data sizes transmitted to the host system in the read command processing by 512 [B] is added to the number of reads. Alternatively, the value of the “data size” designated by the host system 100 may be added to the number of reads. Further, the value of the number of executions of the read command (Host Read Commands) is incremented by 1. Therefore, the health information 700 is updated.

(S1609)

The CPU 130 notifies the host system 100 that the read command processing has been terminated.

(S1610)

After step S1609, the read command processing is terminated.

[Description of Write Command Processing]

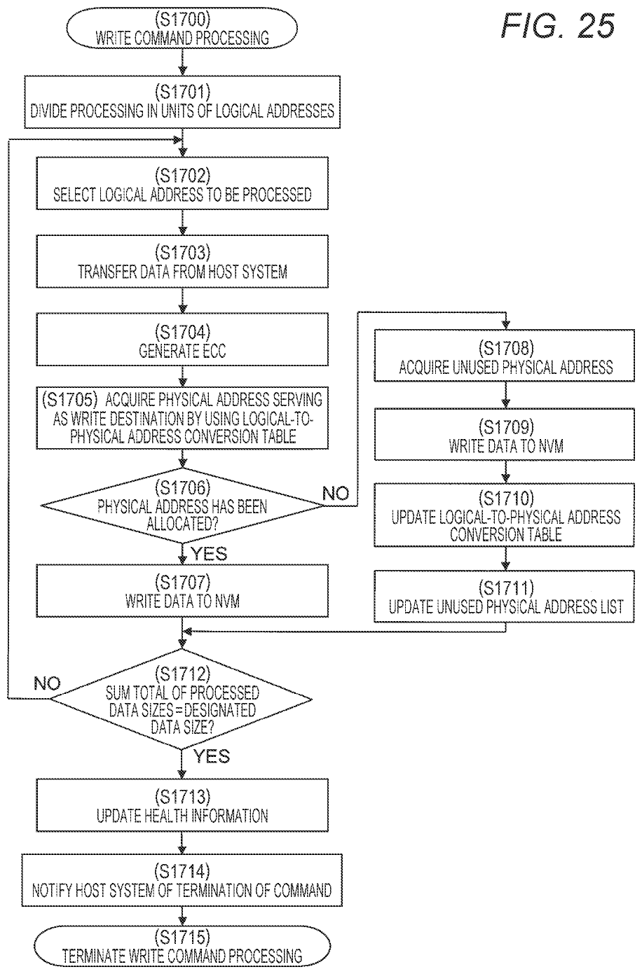

FIG. 25 shows an operation flow of processing executed when the controller 111 receives a write command from the host system 100.

(S1700)

The CPU 130 receives a write command together with information regarding a head logical address to be written and a data size via the host interface unit 140. Therefore, write command processing is started.

(S1701)

The CPU 130 divides write processing in units of logical addresses (in units of logical pages). One logical address is executed in one-time processing. For example, in a case where “0” is designated as a head address to be written and “1” is designated as the data size, one-time processing is performed. Further, in a case where “0” is designated as the head logical address to be read and “2” is designated as the data size, the write processing is divided into two processes. The data size “1” represents an amount of data of one unit, and, for example, “1” is 512 bytes.

(S1702)

The CPU 130 determines logical addresses to be written. The logical addresses to be written are determined in order from the head logical address to be written. In a case where “0” is designated as the head address to be written and “2” is designated as the data size, a logical address to be subjected to the processing first is determined as “0”. A logical address to be subjected to the processing next is determined as “1”.

(S1703)

The CPU 130 receives data to be written (herein, 512 bytes) from the host system 100 via the host interface unit 140 and transmits the received data to the error correction unit 180. The data to be written may be received together with the write command in step S1700.

(S1704)

The error correction unit 180 generates an ECC (herein, 13 bytes) from the data received in step S1703. The received data and the ECC are combined to generate data of 525 bytes.

(S1705)

The CPU 130 determines whether or not there is a physical address allocated to the logical address determined as the address to be written by using the logical-to-physical address conversion table 500 held in the RAM 120. In a case where there is a physical address allocated to the logical address, the physical address is acquired.

(S1706)

In a case where the physical address allocated to the logical address is acquired, the processing proceeds to step S1707. In a case where there is no physical address allocated to the logical address, the processing proceeds to step S1708.

(S1708)

The CPU 130 acquires one physical address from the unused physical address list 600 (see FIG. 19). The physical address may be selected by an arbitrary method. For example, one physical address may be randomly selected, the smallest or largest physical address may be selected, or the physical address may be selected on the basis of other criteria.

(S1709)

The CPU 130 designates the physical address acquired in step S1708 with respect to the NVM 112 and transmits a program request (write request) of the data of 525 bytes generated in step S1704 to the NVM 112.

(S1710)

The CPU 130 adds the physical address acquired in S1708 to the logical-to-physical address conversion table 500 in association with the logical address determined in step S1702.

(S1711)

The CPU 130 deletes the physical address acquired in step S1708 from the unused physical address list.

(S1707)

The CPU 130 designates the physical address acquired in step S1706 with respect to the NVM 112 and transmits a program request (write request) of the data of 525 bytes generated in step S1704 to the NVM 112.

(S1712)

The CPU 130 determines whether or not the sum total of data sizes transmitted so far to the NVM 112 (excluding the sizes of the ECCs) matches the data size designated by the write command. In a case where the sum total of the data sizes transmitted to the NVM 112 (excluding the sizes of the ECCs) matches the data size designated by the write command, the processing proceeds to step S1708. In a case where the sum total of the data sizes does not match the data size, the processing returns to step S1702.

(S1713)

The CPU 130 updates the number of writes (Data Unit Write) and the number of executions of the write command (Host Read Commands) of the health information 700 held in the RAM 120. Specifically, a value obtained by dividing the sum total [B] of the data sizes received from the host system in the write command processing by 512 [B] is added to the number of writes. Alternatively, the value of the “data size” designated by the host system 100 may be added to the number of writes. Further, the value of the number of executions of the write command (Host Read Commands) is incremented by 1. Therefore, the health information 700 is updated.

(S1714)

The CPU 130 notifies the host system 100 that the write command processing has been terminated.

(S1715)

After step S1714, the write command processing is terminated.

[Description of Health Information Reading Processing]

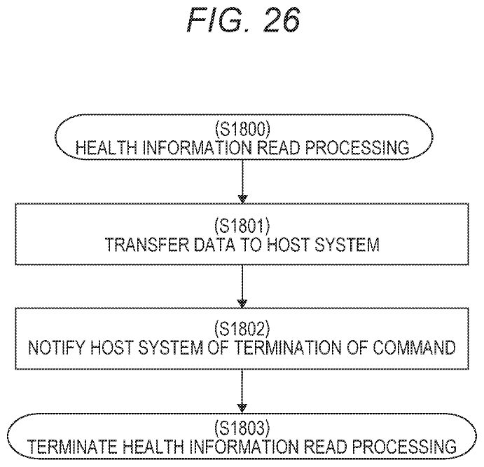

FIG. 26 shows an operation flow of processing executed when the controller 111 receives a read command of the health information from the host system 100.

(S1800)

When the CPU 130 receives a read command of the health information via the host interface unit 140, health information read processing is started.

(S1801)

The CPU 130 reads the health information held in the RAM and transmits the read health information to the host system 100.

(S1802)

The CPU 130 notifies the host system 100 that the health information read processing has been terminated.

(S1803)

After step S1802, the health information read processing is terminated.

The present embodiment employs memory cells having a cross-point structure in which each memory cell stores a bit depending on whether the resistance state is the HRS or the LRS, but can also employ memory cells having other structures as long as the memory cells store bits depending on the first state and the second state. For example, magnetoresistive memory cells, flash memory cells, or the like may be employed. In the magnetoresistive memory cells, bits are stored according to a state of magnetization. In the flash memory, bits are stored according to a charge accumulation state of a floating gate. Memory cells having a structure other than the structures described herein may be used.

According to the present embodiment, the health information is written to the non-volatile memory at a timing of performing the refresh processing, and this eliminates the necessity of writing the health information to the non-volatile memory every time when the health information is updated. This makes it possible to reduce the number of writes to the non-volatile memory. Therefore, it is possible to suppress consumption of the rewrite life of the non-volatile memory.

### Modification Example 1

Modification Example 1 is a modification example of the refresh processing. In the first embodiment, the content of the refresh processing is changed depending on whether or not the address to be refreshed corresponds to the data update refresh address (see FIG. 23). In Modification Example 1, the content of the refresh processing is changed further depending on a value of data read from the address to be refreshed. Specifically, in a case where all bits of data read from the NVM 112 are “1”, there is no need to execute an LRS transition request because the selectors of all the memory cells are turned on by the reading. Therefore, in a case where all the bits of the data read from the NVM 112 are “1”, the LRS transition request is not transmitted to the NVM 112.

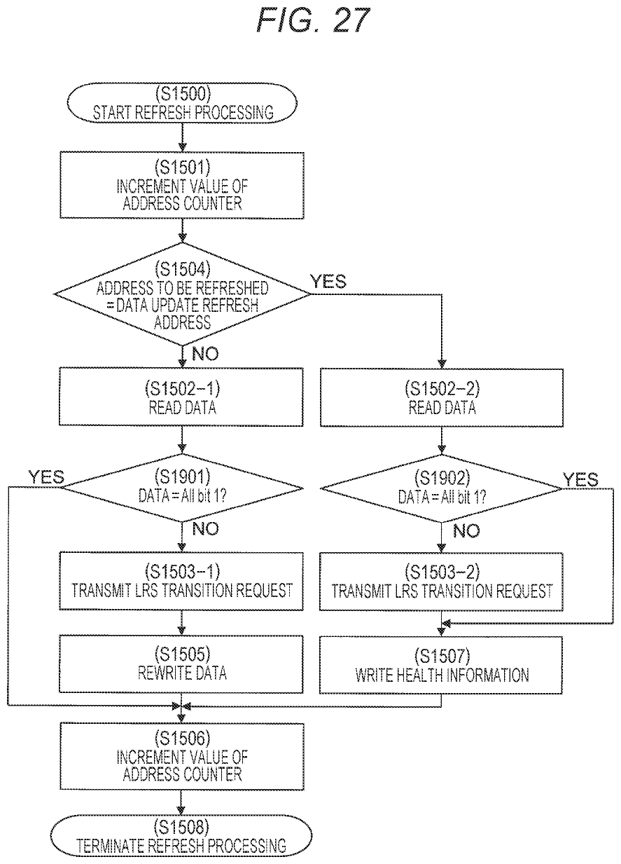

FIG. 27 shows an operation flow of the refresh processing according to Modification Example 1. Steps similar to those in FIG. 23 are denoted by the same reference numerals, and, in a case where there is a plurality of steps having the same content, branch numbers are added to the end of the same reference numeral. Hereinafter, only steps different from those in FIG. 23 will be described. The steps different from those in FIG. 23 are steps S1901 and S1902.

(S1901)

In a case where the address to be refreshed is not the data update refresh address (NO in S1504), the CPU 130 determines whether or not all the bits of the data subjected to the error correction in step S1502 are “1”. In a case where all the bits are “1”, the processing proceeds to step S1506. In this case, transmission of an LRS transition request to the address to be refreshed (S1503-1) and rewriting of data to the NVM 112 (S2014) are not performed. Meanwhile, in a case where at least one bit is “0”, the processing proceeds to step S1503-1, and similar processing to that in FIG. 23 is performed.

(S1902)

In a case where the address to be refreshed is the data update refresh address (YES in S1504), the CPU 130 determines whether or not all the bits of the data subjected to the error correction in step S1502 are “1”. In a case where all the bits are “1”, the processing proceeds to step S1507. In this case, transmission of an LRS transition request to the address to be refreshed (S1503-2) is not performed. Meanwhile, in a case where at least one bit is “0”, the processing proceeds to step S1503-2, and similar processing to that in FIG. 23 is performed.

According to Modification Example 1, in a case where all the bits of the data read from the address to be refreshed (or the data subjected to the error correction) are 1, the execution of the LRS transition request is omitted. This makes it possible to reduce a time of the refresh processing.

### Modification Example 2

Modification Example 2 is a modification example of the refresh processing. In the first embodiment, the content of the refresh processing is changed depending on whether or not the address to be refreshed corresponds to the data update refresh address (see FIG. 23). In Modification Example 2, the content of the refresh processing is changed further depending on whether or not the address to be refreshed corresponds to a physical address (unused physical address) allocated to no logical address. Specifically, in a case where the address to be refreshed is not the data update refresh address and the address to be refreshed is an unused physical address, an LRS transition request and rewriting of data to the NVM 112 are omitted. This is because no data is originally written to the unused physical address and there is no need to write back data.

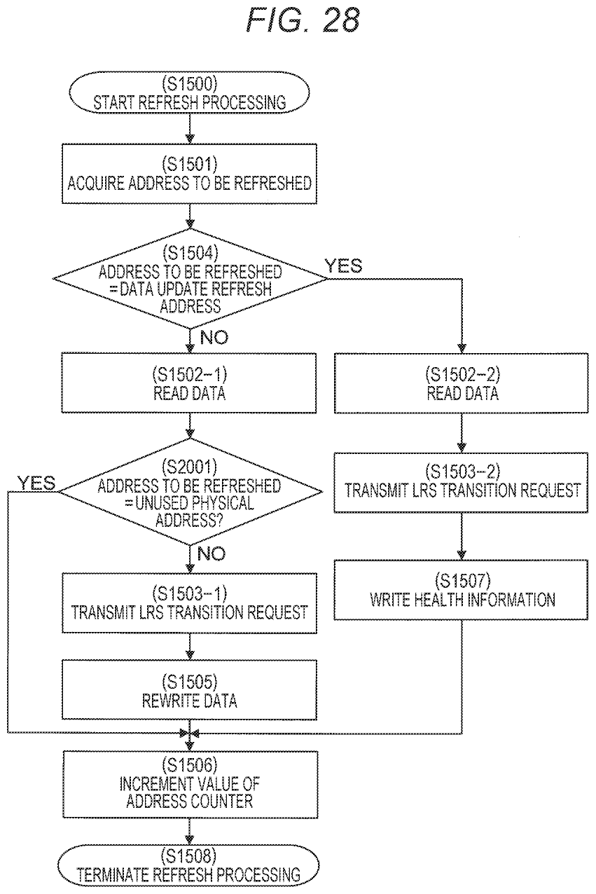

FIG. 28 shows an operation flow of the refresh processing according to Modification Example 2. Steps similar to those in FIG. 23 are denoted by the same reference numerals, and, in a case where there is a plurality of steps having the same content, branch numbers are added to the end of the same reference numeral. Hereinafter, only a step different from that in FIG. 23 will be described. The step different from that in FIG. 23 is step S2001.

(S2001)

In a case where the address to be refreshed is not the data update refresh address (NO in S1504), the CPU 130 determines whether or not the address to be refreshed is registered in the unused physical address list 600 on the basis of the unused physical address list 600. The unused physical address is an address to which no data is written. In a case where the address to be refreshed is registered in the unused physical address list 600, that is, in a case where the address to be refreshed is an unused physical address, the processing proceeds to step S1506. In this case, transmission of an LRS transition request to the address to be refreshed (S1503-1) and rewriting of data to the NVM 112 (S2014) are not performed. Meanwhile, in a case where the address to be refreshed is not registered in the unused physical address list 600, that is, in a case where the address to be refreshed is not an unused physical address, the processing proceeds to step S1503-1, and similar processing to that in FIG. 23 is performed.

According to Modification Example 2, in a case where the address to be refreshed is an unused physical address, the execution of the LRS transition request is omitted. This makes it possible to reduce the time of the refresh processing.

### Modification Example 3

In Modification Example 3, data of a memory cell storing unnecessary data is erased when the refresh processing is executed. This makes it possible to omit rewriting of data.

SSDs generally perform processing called wear leveling in order to prevent a specific memory cell from being concentratedly rewritten. In the wear leveling, the number of rewrites that have thus occurred is counted with a page or a plurality of pages as a unit. One page corresponds to, for example, data of one physical address (e.g., 512 bytes), but one page may correspond to a plurality of physical addresses. The number of rewrites is counted for each physical address, and data of the physical address in which rewrite frequently occurs is copied to an unused physical address. As the unused physical address, a physical address having a small number of rewrites is selected. Therefore, the number of rewrites is averaged among the physical addresses. After copying the data, the data of the physical address serving as a copy source becomes unnecessary.

Further, in a case where unnecessary data is generated due to deletion or rewriting of data in an SSD, the host system notifies the controller of the memory system of a logical address in which the unnecessary data is recorded by using a trim command. The controller can handle the data in a physical address corresponding to the logical address as the unnecessary data.

In Modification Example 3, regarding a physical address storing unnecessary data as in the above two examples, the data is erased and the data is not rewritten at the time of the refresh processing. Such refresh is referred to as data erasure refresh. In the refresh operation reference table, “data erasure refresh” is registered as the refresh method for a physical address to be subjected to the data erasure refresh. A physical address whose refresh method is the data erasure refresh is referred to as a data erasure refresh address.

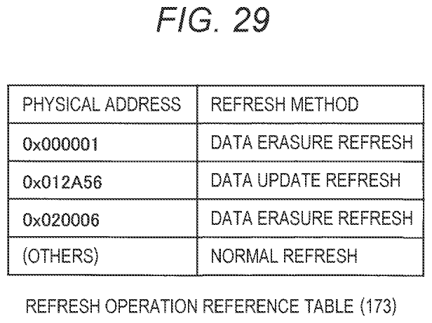

FIG. 29 shows an example of the refresh operation reference table 173 according to Modification Example 3. The refresh operation reference table 173 is held in the RAM 120. In the example of FIG. 29, the “data erasure refresh” is designated for two physical addresses. The “data update refresh” and the “normal refresh” are similar to those in the first embodiment.

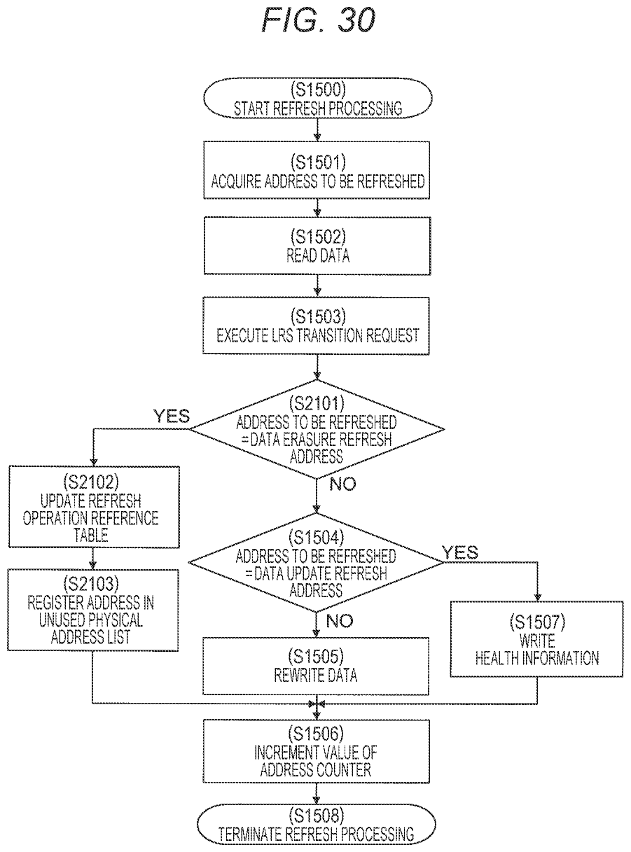

FIG. 30 shows an operation flow of the refresh processing according to Modification Example 3. Steps similar to those in FIG. 23 are denoted by the same reference numerals. Hereinafter, only a step different from that in FIG. 23 will be described. The steps different from those in FIG. 23 are steps S2101, S2102, and S2103.

(S2101)

On the basis of the refresh operation reference table 173, the CPU 130 determines whether or not the refresh method of the address to be refreshed is the data erasure refresh, that is, whether or not the address to be refreshed corresponds to the data erasure refresh address. In a case where the address to be refreshed does not correspond to the data erasure refresh address, the processing proceeds to step S1504. Step S1504 and subsequent steps are the same as those in FIG. 23. In a case where the address to be refreshed corresponds to the data erasure refresh address, the processing proceeds to step S2102.

(S2102)

In a case where the address to be refreshed corresponds to the data erasure refresh address, the CPU 130 updates the refresh method of the address to be refreshed from the data erasure refresh to the normal refresh in the refresh operation reference table 173. That is, the address to be refreshed is updated from the data erasure refresh address to a normal refresh address. Therefore, the data of the address to be refreshed is erased.

(S2103)

The CPU 130 registers the address to be refreshed in the unused physical address list 600. Thereafter, the processing proceeds to step S1506. Step S1506 and a subsequent step are the same as those in FIG. 23.

According to Modification Example 3, it is possible to reduce the time of the refresh processing by omitting the rewriting of unnecessary data. Further, it is also possible to suppress the consumption of the rewrite life.

Note that the above-described embodiments show examples for embodying the present disclosure, and the present disclosure can be implemented in various other forms. For example, various modifications, substitutions, omissions, or combinations thereof can be made within the gist of the present disclosure. Such modifications, substitutions, omissions, and the like are also included in the scope of the present disclosure and are similarly included in the invention recited in the claims and the scope equivalent to the invention.

Further, the effects of the present disclosure described in the present specification are merely examples, and other effects may be obtained.

Note that the present disclosure can also have the following configurations.

[Item 1]

A controller according to one aspect of the present invention including:

a first interface unit connected to a non-volatile memory including a plurality of blocks of memory cells that enter into both a first state and a second state and in which a plurality of addresses is allocated to the plurality of blocks;

an information holding unit that holds first information; and

a control unit that

reads first data from a first block of the non-volatile memory via the first interface unit,

specifies the memory cell in the second state among the memory cells in the first block and writes second data for causing the specified memory cell in the second state to transition to the first state, and

selects one of the first information and the first data on the basis of the address of the first block and writes the selected first information or first data to the first block.

[Item 2]

The controller according to the item 1, in which

the control unit writes the first information in a case where the address of the first block is a first address and writes the first data in a case where the address of the first block is not the first address.

[Item 3]

The controller according to the item 1 or 2, in which:

the memory cell includes a selector and a variable resistor connected in series;

the first state and the second state are different states of the variable resistor; and

the selector is turned on at a voltage equal to or higher than a threshold, and the threshold increases as time elapses after the selector is turned on.

[Item 4]

The controller according to any one of the items 1 to 3, in which

the first state is a low resistance state, and the second state is a high resistance state.

[Item 5]

The controller according to any one of the items 1 to 4, in which

the control unit determines whether the memory cells of the first block are in the first state or the second state on the basis of the first data.

[Item 6]

The controller according to any one of the items 1 to 5, further including

a buffer that holds the first data read from the first block of the non-volatile memory.

[Item 7]

The controller according to any one of the items 1 to 6, in which:

the first data includes an error correction code;

the controller further includes an error correction unit that corrects an error of the first data on the basis of the error correction code; and

the control unit writes the first data subjected to the error correction to the first block.

[Item 8]

The controller according to any one of the items 1 to 7, in which:

the first information indicates a state of the non-volatile memory; and

the control unit updates the first information of the information holding unit in accordance with the state of the non-volatile memory.

[Item 9]

The controller according to the item 8, in which:

the first information includes a cumulative value of the number of writes or the number of reads of the non-volatile memory; and

the control unit updates the first information of the information holding unit every time when the non-volatile memory is written or read.

[Item 10]

The controller according to the item 8 or 9, further including

a second interface unit connected to a host system, in which:

the control unit receives a write or read command from the host system via the second interface unit and performs write to or read from the non-volatile memory in response to the command;

the first information includes a cumulative value of the number of executions of the command; and

the control unit updates the first information of the information holding unit every time when the command is executed.

[Item 11]

The controller according to any one of the items 8 to 10, in which:

the first information includes a startup time of the non-volatile memory; and

the control unit updates the first information of the information holding unit as time elapses.

[Item 12]

The controller according to any one of the items 1 to 11, in which:

the first state corresponds to a first value;

the second state corresponds to a second value; and

the control unit does not write the second data in a case where all bits of the first data have the first value.

[Item 13]

The controller according to any one of the items 1 to 12, in which:

the first state corresponds to a first value;

the second state corresponds to a second value; and

the control unit does not write the first data in a case where the address of the first block is not the first address and all bits of the first data have the first value.

[Item 14]

The controller according to any one of the items 1 to 13, in which

the control unit does not write the first data in a case where the address of the first block is not the first address and the address of the first block is a second address.

[Item 15]

The controller according to the item 14, in which

the second address is an address of an unused block among the plurality of blocks.

[Item 16]

The controller according to the item 14, in which

the second address is an address of a block storing unnecessary data among the plurality of blocks.

[Item 17]

The controller according to any one of the items 1 to 16, in which

the control unit sequentially selects the plurality of blocks in the non-volatile memory, and

defines the selected block as the first block.

[Item 18]

A memory system including:

a non-volatile memory that includes a plurality of blocks of memory cells that enter into both a first state and a second state and in which a plurality of addresses is allocated to the plurality of blocks; and

a controller including an information holding unit that holds first information and a control unit, in which:

the control unit

reads first data from a first block of the non-volatile memory,

specifies the memory cell in the second state among the memory cells in the first block and writes second data for causing the specified memory cell in the second state to transition to the first state, and

selects one of the first information and the first data on the basis of the address of the first block and writes the selected first information or first data to the first block.

[Item 19]

A method of controlling a memory, the method including:

reading first data from a first block of a non-volatile memory that includes a plurality of blocks of memory cells that enter into both a first state and a second state and in which a plurality of addresses is allocated to the plurality of blocks;

specifying the memory cell in the second state among the memory cells in the first block and writing second data for causing the specified memory cell in the second state to transition to the first state; and

selecting one of first information held in an information holding unit and the first data on the basis of the address of the first block and writing the selected first information or first data to the first block.

### REFERENCE SIGNS LIST

100 Host system
110 Memory system
111 Controller
112 Non-volatile memory
200 Interface unit
201 Request processing unit
202 Verification unit
203 Buffer
205 Read control unit
206 Program control unit
207 Voltage pulse control unit
208 Word line control unit
209 Bit line control unit
210 Memory cell array
203 Buffer
300 Write data buffer
301 Read data buffer
302 Verification buffer
401 Memory cell
510 Selector
520 Variable resistor
120 RAM
130 CPU
140 Host interface unit
150 NVM interface unit
160 ROM
170 Refresh control unit
180 Error correction unit
190 Bus
171 Timer
172 Address counter
173 Refresh operation reference table
174 Refresh data buffer
500 Logical-to-physical address conversion table
600 Unused physical address list
700 Health information

1. A controller comprising:
a first interface unit connected to a non-volatile memory including a plurality of blocks of memory cells that enter into both a first state and a second state and in which a plurality of addresses is allocated to the plurality of blocks;
an information holding unit that holds first information; and
a control unit that
reads first data from a first block of the non-volatile memory via the first interface unit,
specifies the memory cell in the second state among the memory cells in the first block and writes second data for causing the specified memory cell in the second state to transition to the first state, and
selects one of the first information and the first data on a basis of the address of the first block and writes the selected first information or first data to the first block.

2. The controller according to claim 1, wherein
the control unit writes the first information in a case where the address of the first block is a first address and writes the first data in a case where the address of the first block is not the first address.

3. The controller according to claim 1, wherein:
the memory cell includes a selector and a variable resistor connected in series;
the first state and the second state are different states of the variable resistor; and
the selector is turned on at a voltage equal to or higher than a threshold, and the threshold increases as time elapses after the selector is turned on.

4. The controller according to claim 2, wherein
the first state is a low resistance state, and the second state is a high resistance state.

5. The controller according to claim 1, wherein
the control unit determines whether the memory cells of the first block are in the first state or the second state on a basis of the first data.

6. The controller according to claim 1, further comprising
a buffer that holds the first data read from the first block of the non-volatile memory.

7. The controller according to claim 1, wherein:
the first data includes an error correction code;
the controller further includes an error correction unit that corrects an error of the first data on a basis of the error correction code; and
the control unit writes the first data subjected to the error correction to the first block.

8. The controller according to claim 1, wherein:
the first information indicates a state of the non-volatile memory; and
the control unit updates the first information of the information holding unit in accordance with the state of the non-volatile memory.

9. The controller according to claim 8, wherein:
the first information includes a cumulative value of the number of writes or the number of reads of the non-volatile memory; and
the control unit updates the first information of the information holding unit every time when the non-volatile memory is written or read.

10. The controller according to claim 8, further comprising
a second interface unit connected to a host system, wherein:
the control unit receives a write or read command from the host system via the second interface unit and performs write to or read from the non-volatile memory in response to the command;
the first information includes a cumulative value of the number of executions of the command; and
the control unit updates the first information of the information holding unit every time when the command is executed.

11. The controller according to claim 8, wherein:
the first information includes an operating time of the non-volatile memory; and
the control unit updates the first information of the information holding unit as time elapses.

12. The controller according to claim 1, wherein:
the first state corresponds to a first value;
the second state corresponds to a second value; and
the control unit does not write the second data in a case where all bits of the first data have the first value.

13. The controller according to claim 2, wherein:
the first state corresponds to a first value;
the second state corresponds to a second value; and
the control unit does not write the first data in a case where the address of the first block is not the first address and all bits of the first data have the first value.

14. The controller according to claim 2, wherein
the control unit does not write the first data in a case where the address of the first block is not the first address and the address of the first block is a second address.

15. The controller according to claim 14, wherein
the second address is an address of an unused block among the plurality of blocks.

16. The controller according to claim 14, wherein
the second address is an address of a block storing unnecessary data among the plurality of blocks.

17. The controller according to claim 1, wherein
the control unit sequentially selects the plurality of blocks in the non-volatile memory, and
defines the selected block as the first block.

18. A memory system comprising:
a non-volatile memory that includes a plurality of blocks of memory cells that enter into both a first state and a second state and in which a plurality of addresses is allocated to the plurality of blocks; and
a controller including an information holding unit that holds first information and a control unit, wherein:
the control unit
reads first data from a first block of the non-volatile memory,
specifies the memory cell in the second state among the memory cells in the first block and writes second data for causing the specified memory cell in the second state to transition to the first state, and
selects one of the first information and the first data on a basis of the address of the first block and writes the selected first information or first data to the first block.

19. A method of controlling a memory, the method comprising:
reading first data from a first block of a non-volatile memory that includes a plurality of blocks of memory cells that enter into both a first state and a second state and in which a plurality of addresses is allocated to the plurality of blocks;
specifying the memory cell in the second state among the memory cells in the first block and writing second data for causing the specified memory cell in the second state to transition to the first state; and
selecting one of first information held in an information holding unit and the first data on a basis of the address of the first block and writing the selected first information or first data to the first block.
